(19) United States
(12) Patent Application Publication
(10) Pub. No.: US 2012/0194033 A1
(43) Pub. Date: Aug. 2, 2012

(54) ACOUSTIC WAVE DEVICE AND METHOD FOR FABRICATING THE SAME

(75) Inventor: Keiji TSUDA, Kanagawa (JP)

(73) Assignee: TAIYO YUDEN CO., LTD., Tokyo (JP)

(21) Appl. No.: 13/326,559

(22) Filed: Dec. 15, 2011

(30) Foreign Application Priority Data
Feb. 1, 2011 (JP) 2011-020248

(51) Int. Cl. H01L 41/047

(52) U.S. Cl. 310/313 C

(57) ABSTRACT

An acoustic wave device includes a piezoelectric substrate, interdigitated electrodes formed on the piezoelectric substrate, and an insulation film that is formed on a surface of the interdigitated electrodes by atomic layer deposition and includes aluminum oxide.

### CROSS-REFERENCE TO RELATED APPLICATION

This application is based upon and claims the benefit of priority of the prior Japanese Patent Application No. 2011-020248, filed on Feb. 1, 2011, the entire contents of which are incorporated herein by reference.

### FIELD

An aspect of the invention discussed herein is related to a duplexer and a method for fabricating the same.

### BACKGROUND

There is known an acoustic wave device in which an interdigital transducer (IDT) is formed on a piezoelectric substrate. An example of such an acoustic wave device is a surface acoustic wave (SAW) filter. There is known an art of covering surfaces of comb-like electrodes or interdigitated electrodes that form the IDT with an insulation film made of, for example, silicon oxide, silicon nitride or aluminum oxide (see Japanese Patent Application Publication Nos. 10-135766 and 2008-135999).

In some cases, the thickness of the insulation film formed on the surfaces of the interdigitated electrodes changes the filter characteristics of the acoustic wave device (for example, the center frequency). It is thus difficult to adjust the filter characteristics to desired values at the time of forming the insulation film. Therefore, it is necessary to adjust the filter characteristics to desired values after the device chip is completed. This increases the number of fabrication steps.

The insulation film made of aluminum oxide may not cover the interdigitated electrode well. Thus, electrostatic breakdown of the interdigitated electrode may take place in such a way to begin at a defective portion of the insulation film because resin is charged in molding after the acoustic wave device is completed. Thus, the reliability of the acoustic wave device is degraded.

### SUMMARY OF THE INVENTION

According to an aspect of the present invention, there is provided an acoustic wave device including: a piezoelectric substrate; interdigitated electrodes formed on the piezoelectric substrate; and an insulation film that is formed on a surface of the interdigitated electrodes by atomic layer deposition and includes aluminum oxide.

### BRIEF DESCRIPTION OF THE DRAWINGS

FIGS. 1A through 1E are schematic cross-sectional views that illustrate a method for fabricating an acoustic wave device in accordance with a first embodiment;

FIGS. 2A through 2C are views of the acoustic wave device of the first embodiment;

FIG. 3 is a plan view of an acoustic wave device used in an experiment;

FIGS. 4A through 4C are graphs of experimental results of measuring the center frequencies of acoustic wave devices;

FIG. 5 is a plan view of an acoustic wave device in accordance with a variation of the first embodiment;

FIG. 6 is a plan view of an acoustic wave device in accordance with another variation of the first embodiment;

FIG. 7 is a plan view of an acoustic wave device in accordance with yet another variation of the first embodiment;

FIG. 8 is a plan view of an acoustic wave device used in an experiment;

FIG. 9 is a graph of experimental results of measuring the center frequencies of acoustic wave devices;

FIG. 10 is a plan view of an acoustic wave device in accordance with a further variation of the first embodiment;

FIG. 11 illustrates experimental results of measuring the breakdown voltages of acoustic wave devices;

FIGS. 12A through 12C are cross-sectional views of variations of interdigitated electrodes;

FIGS. 13A through 13D are cross-sectional views that illustrate a method for fabricating an acoustic wave device in accordance with a second embodiment;

FIGS. 14A and 14B are cross-sectional views that illustrate steps that follow the steps of FIGS. 13A through 13D; and

FIGS. 15A and 15B are cross-sectional views of an acoustic wave device in accordance with a variation of the second embodiment.

### DETAILED DESCRIPTION

### First Embodiment

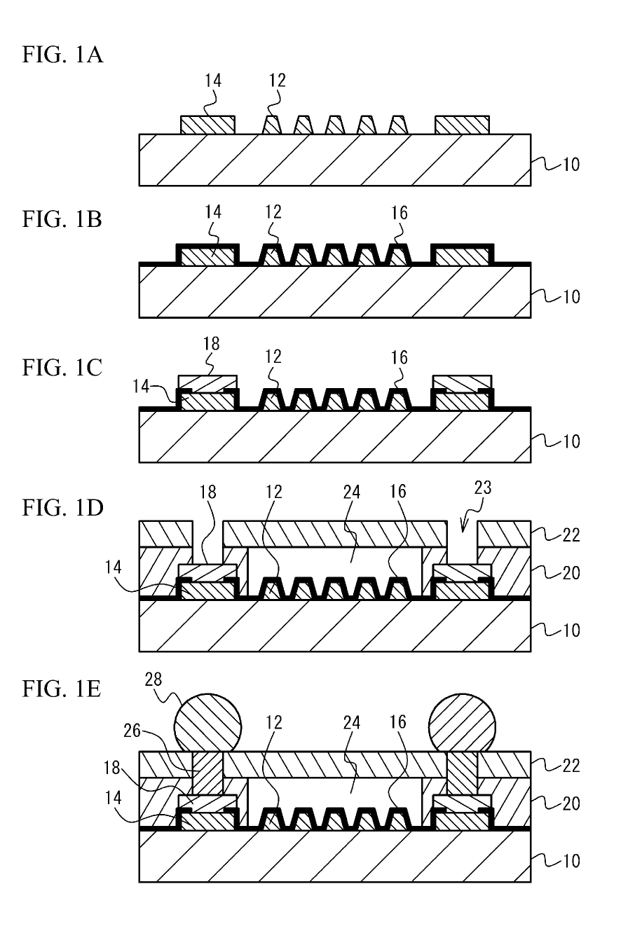

FIGS. 1A through 1E are cross-sectional views that illustrate a method for fabricating an acoustic wave device in accordance with a first embodiment. As illustrated in FIG. 1A, interdigitated electrodes 12 that are part of the IDT and electrode pads 14 for external connections are formed on a piezoelectric substrate 10. The piezoelectric substrate 10 may be a LiNbO₃ substrate or a LiTaO₃ substrate, for example. The interdigitated electrodes 12 and the electrode pads 14 may be made of, for example, aluminum. The interdigitated electrodes 12 and the electrode pads 14 may be formed by, for example, a vapor deposition method and a liftoff method. The interdigitated electrodes 12 and the electrode pads 14 may be 350 nm thick, for example.

As illustrated in FIG. 1B, an insulation film 16 is formed on the surfaces of the piezoelectric substrate 10, the interdigitated electrodes 12 and the electrode pads 14. The insulation film 16 is made of aluminum oxide and is formed by, for example, thermal atomic layer deposition (ALD). For example, precursor tetra methyl aluminum (TMA) and an oxidizing agent (water or ozone) are reacted with each other to form the insulation film 16. For example, the thickness of the insulation film 16 is 50 nm, and the growth rate thereof is 0.101 nm per second. The thermal ALD may be replaced with plasma ALD.

Referring to FIG. 1C, parts of the insulation film 16 are removed to expose the electrode pads 14. The removal of the insulation film 16 may be carried out by dry etching using BCl₃ gas, for example. The etching rate may be 1 nm per second, for example. Then, a metal layer 18 for making electrical connections with an outside of the device are formed on the upper surfaces of the exposed electrode pads 14 and the peripheral insulation film 16. The metal layer 18 may be formed by serially depositing Ti and Au in this order by the vapor deposition method. The metal layer 18 may be 600 nm thick, for example.

Then, as illustrated in FIG. 1D, seal layers 20 and 22 are formed on the piezoelectric substrate 10 so as to cover the interdigitated electrodes 12. The seal layers 20 and 22 may be formed by providing resin (for example, epoxy photosensitive resin) on the insulation film 16 and the metal layer 18 by a tenting method and developing the resin. The seal layer 20 on the interdigitated electrodes 12 is removed to define a cavity 24. Through holes 23 that pierce the seal layers 20 and 22 are formed above the metal layer 18. The thickness from the piezoelectric substrate 10 to the upper surface of the seal layer 22 is, for example, 75 μm.

Referring to FIG. 1E, electrode posts 26 are formed in the through holes 23. The electrode posts 26 may be made of, for example, Ni and may be formed by plating. The lower surfaces of the electrode posts 26 contact the electrode pads 14, and the side surfaces thereof contact the seal layers 20 and 22. Finally, solder balls 28 for external connections are formed on the upper surfaces of the electrode posts 26. Through the above fabrication steps, the device chip (prior to packaging) of the acoustic wave device of the first embodiment is obtained.

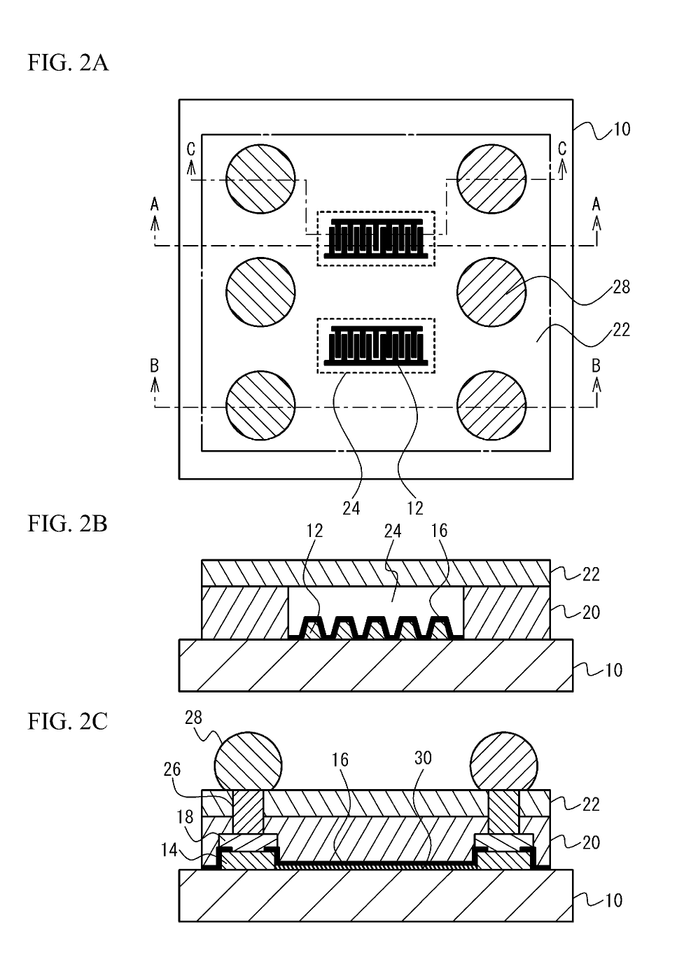

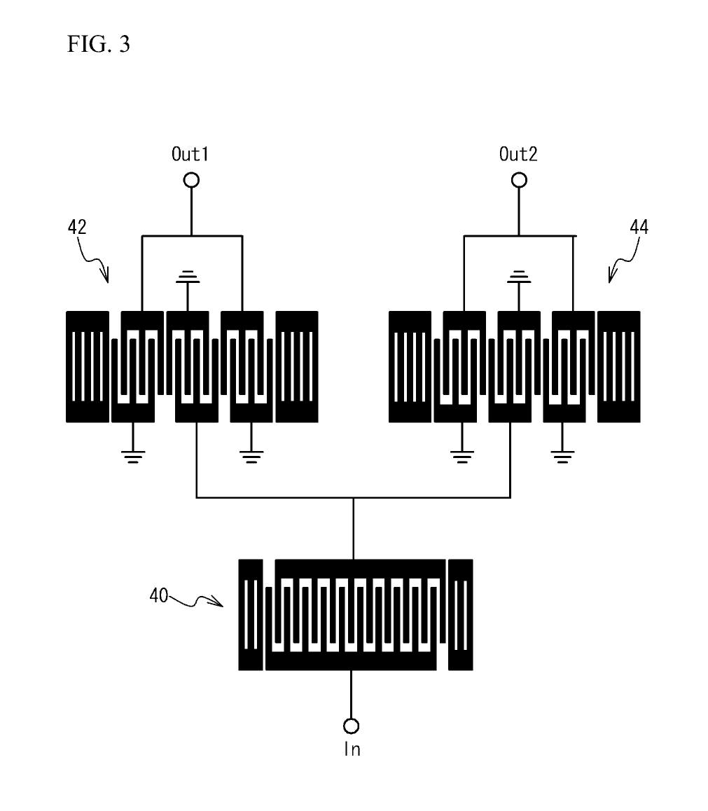

FIGS. 2A through 2C are diagrams of a device chip of the duplexer according to the first embodiment. FIG. 2A is a schematic plan view of the device chip, FIG. 2B is a schematic cross-sectional view taken along a line A-A in FIG. 2A, and FIG. 2C is a schematic cross-sectional view taken along a line B-B in FIG. 2A. The cross-sectional views of FIGS. 1A through 1E are those taken along a line C-C in FIG. 2A. In FIG. 2A, interconnection lines that interconnect the interdigitated electrodes 12 and the electrode pads 14 are not illustrated for the sake of simplicity. As illustrated in FIGS. 2A and 2B, the cavity 24 defined by the seal layers 20 and 22 is located above the area in which the interdigitated electrodes 12 are formed. As illustrated in FIG. 2C, the electrode pads located on the opposite sides of the device chip are electrically connected together by an electrode interconnection line 30 formed on the piezoelectric substrate 10. In FIGS. 1A through 1E and 2A through 2C, the interdigitated electrodes are schematically illustrated so as to have a smaller number of fingers than the real number (this holds true for the other figures).

It may be considered that the insulation film 16 in FIG. 1B may be formed by a physical vapor deposition (PVD) method or a chemical vapor deposition (CVD) method. However, the insulation film 16 formed by the above methods may not cover the surfaces of the interdigitated electrodes 12 properly. Particularly, in a case where the interdigitated electrodes 12 are made of a material including copper (for example, aluminum alloy including copper), the property of covering or coverage may deteriorate. Thus, electrostatic breakdown of the interdigitated electrode may take place in such a way to begin at a defective portion of the insulation. Such electrostatic breakdown arises from resin charged in molding after the acoustic wave device is completed.

The thickness of the insulation film 16 formed by the PVD or CVD method may change the filter characteristics of the acoustic wave device (for example, the center frequency). It is thus difficult to adjust the filter characteristics to desired values in the fabrication steps illustrated in FIGS. 1A through 1E. Therefore, there is a need to adjust the filter characteristics after the device chip is completed. This increases the number of fabrication steps.

In contrast, according to the fabrication method of the first embodiment, the insulation film 16 is formed by the ALD method. In the ALD method, molecules react with the surfaces of the interdigitated electrodes 12 and the electrode pads 14 one at a time to grow the insulation film 16. It is thus possible to improve the coverage of the interdigitated electrodes 12 by the insulation film 16 and suppress electrostatic breakdown of the interdigitated electrodes 12 and to improve the reliability of the acoustic wave device.

A change of the thickness of the insulation film 16 formed by the ALD method does not change the filter characteristics of the acoustic wave devices greatly. It is thus possible to stabilize the filter characteristics of the acoustic wave device and omit the step of adjusting the filter characteristics after completion of the device chip.

As described above, the first embodiment forms the insulation film 16 by the ALD method so that the filter characteristics can be stabilized and the reliability can be improved. It is to be noted that a person skilled in the art can determine whether the insulation film 16 has been formed by the ALD method or not even after the device chip is completed. Such determination may be done by observing a cross section of the device chip using a transmission electron microscope (TEM) or analyzing the device chip using a secondary ion-microprobe mass spectrometer (SIMS).

A description is now given of experimental results obtained by using the acoustic wave device of the first embodiment.

FIG. 3 is a schematic plan view of an acoustic wave device used in an experiment in which a filter structure of the acoustic wave device is illustrated. The acoustic wave device illustrated in FIG. 3 is a double mode surface acoustic wave (DMS) filter having two surface acoustic wave (SAW) filters connected in parallel. The DMS filter has a resonator 40 connected to an unbalanced input terminal In, a first filter 42 connected to a balanced output terminal Out1, and a second filter 44 connected to a balanced output terminal Out2. Each of the first filter 42 and the second filter 44 has three IDTs interposed between reflection electrodes. The center IDT of the first filter 42 is connected to the resonator 40, and the two remaining IDTs located at both sides of the center IDT are connected to the output terminal Out1. Similarly, the center IDT of the second filter 44 is connected to the resonator 40, and the two remaining IDTs located at both sides of the center IDT are connected to the output terminal Out2.

In the experiment, the interdigitated electrodes 12 of the IDTs were made of aluminum, and were 160 nm thick. The interdigitated electrodes 12 had a pitch of 1032.7 nm, and a ratio of the electrode finger length to the spacing between the adjacent fingers (L/S ratio) was set to 60%. The insulation film 16 was formed on the acoustic wave devices configured as described above by the following three different methods. The first method formed the insulation film 16 made of aluminum oxide (for example, Al₂O₃) by the PVD method. The second method formed the insulation film 16 made of silicon cyanide (SiCN) by the CVD method. The third method formed the insulation film 16 made of aluminum oxide (for example, Al₂O₃) by the ALD method (the first embodiment). The experiment measured changes of the center frequencies of the acoustic wave devices with the insulation films 16 formed by the above methods.

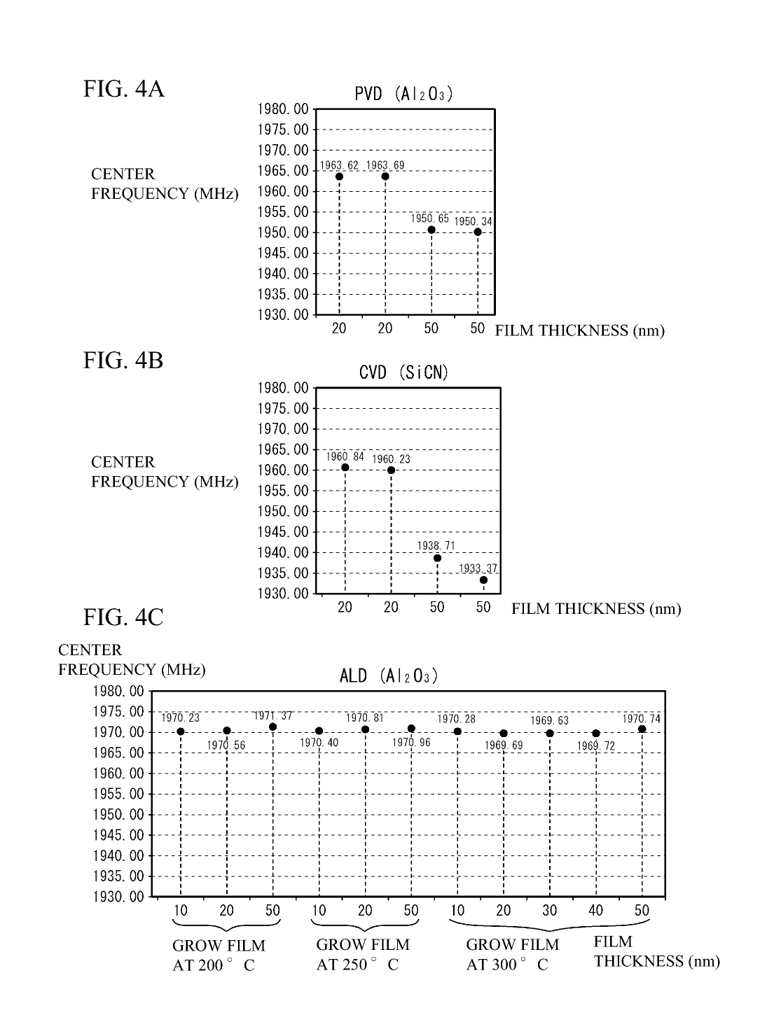

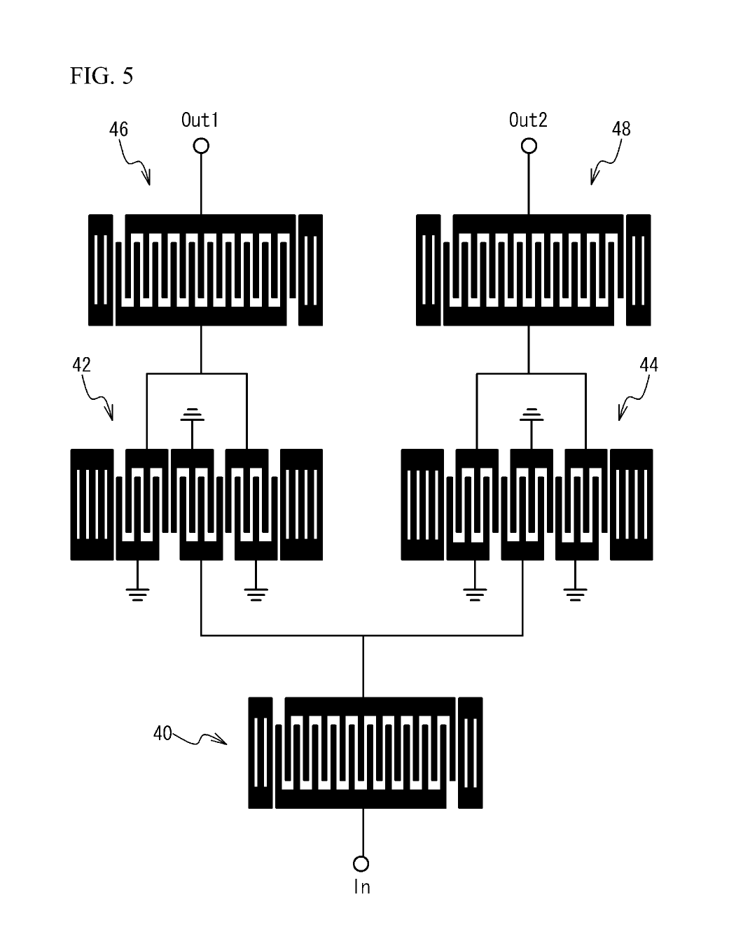

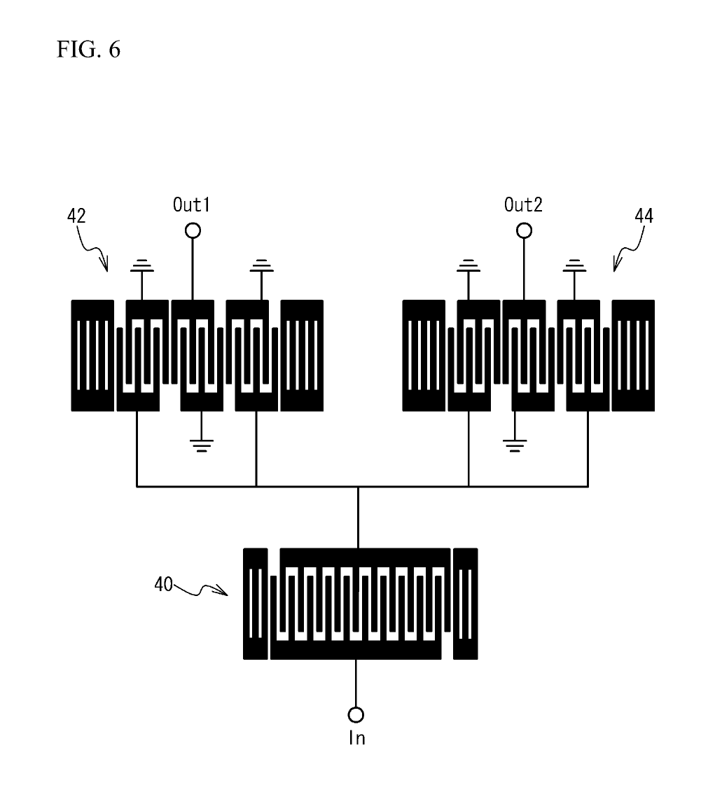

FIGS. 4A through 4C are graphs of experimental results. FIG. 4A illustrates an experimental result of the PVD method (sputtering), FIG. 4B illustrates an experimental result of the CVD method, and FIG. 4C illustrates an experimental result of the ALD method. In FIGS. 4A and 4B, two thicknesses of the insulation films 16 were prepared. More particularly, a thickness of 20 nm of the insulation film 16 and a thickness of 50 nm were prepared. The measurement was carried out twice for each thickness. As illustrated in FIGS. 4A and 4B, a change of the thickness from 20 nm to 50 nm changed the center frequency of the filter. In the case of the PVD method (aluminum oxide), the center frequency became low by 13 MHz, and a reduction of the passband per 1 nm was 0.43 MHz. In the case of the CVD method (silicon cyanide), the center frequency become low by 25 MHz, and a reduction of the passband per 1 nm was 0.83 MHz.

In FIG. 4C, the insulation film 16 was grown at different temperatures of 200° C., 250° C. and 300° C. At each of the three temperatures, the thickness of the insulation film 16 was changed in the measurement of a change of the center frequency. More particularly, at each of the 200° C. and 250° C., the film thickness was changed to 10 nm, 20 nm and 50 nm. At 300° C., the film thickness was changed to 10 nm, 20 nm, 30 nm, 40 nm and 50 nm. As illustrated in FIG. 4C, at any of the growth temperatures, the center frequency hardly changes due to the change of the film thickness. Similarly, the center frequency hardly changes due to the change of the growth temperature.

As described above, the acoustic wave device (DMS filter) with the insulation film 16 formed by the ALD method has a smaller change of the center frequency than changes of the center frequencies of the acoustic wave devices formed by the PVD method and the CVD method, and has stabilized filter characteristics.

The structure of DMS is not limited to that used in the experiment and illustrated in FIG. 3.

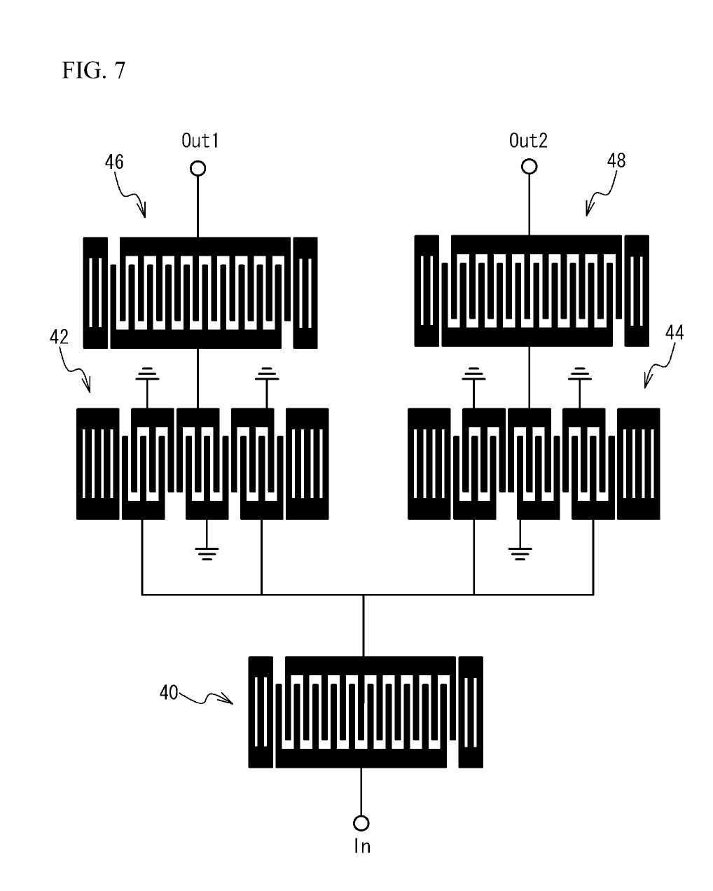

FIGS. 5 through 7 are schematic plan views of variations of DMS filters connected in parallel. A structure In FIG. 5 is obtained by varying the structure in FIG. 3 so that a resonator 46 is provided between the first filter 42 and the output terminal Out1 and a resonator 48 is provided between the second filter 44 and the output terminal Out2. The remaining structures of FIG. 5 are the same as those of FIG. 3. A structure in FIG. 6 has connections with the IDTs different from those in FIG. 3. The center IDT of the first filter 42 is connected to the output terminal Out1, and the two IDTs located at both sides of the center IDT are connected to the resonator 40. Similarly, the center IDT of the second filter 44 is connected to the output terminal Out2, and the two IDTs located at both sides of the center IDT are also connected to the resonator 40. A structure in FIG. 7 is obtained by varying the structure in FIG. 6 so that the resonator 46 is provided between the first filter 42 and the output terminal Out1, and the resonator 48 is provided between the second filter 44 and the output terminal Out2. The variations with the insulation films 16 formed by the ALD method have stabilized filter characteristics.

A description is now given of experimental results obtained by using DMS filters connected in series.

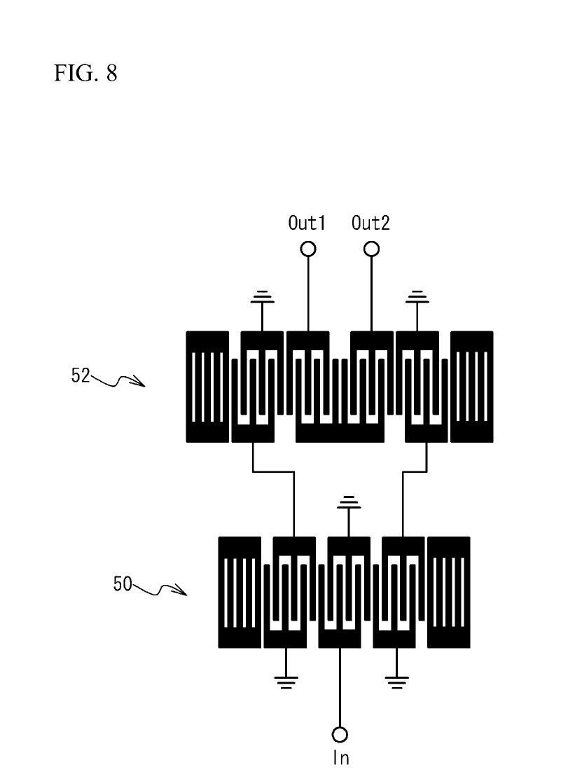

FIG. 8 is a schematic plan view of an acoustic wave device used in the experiment. The acoustic wave device illustrated in FIG. 8 has a first filter 50 connected to the unbalanced input terminal In, and a second filter 52 connected to the balanced output terminals Out1 and Out2. The first filter 50 has three IDTs interposed between two reflection electrodes. The second filter 52 has four IDTs interposed between two reflection electrodes. The center IDT of the first filter 50 is connected to the input terminal In, and the remaining two IDTs are connected to the second filter 52. The two center IDTs of the second filter 52 are connected to the output terminals Out1 and Out2, respectively, and the remaining two IDTs provided further out than the two center IDTs are connected to the first filter 50.

In the experiment, the interdigitated electrodes 12 of the IDTs were made of aluminum and was 340 nm thick. The interdigitated electrodes 12 had a pitch of 1575.5 nm, and an L/S ratio of 69%. The insulation film 16 was formed on the acoustic wave devices configured as described above by the following two different methods. The first method formed the insulation film 16 made of silicon oxide by the PVD method. The second method formed the insulation film 16 made of aluminum oxide by the ALD method (the first embodiment). The experiment measured changes of the center frequencies of the acoustic wave devices with the insulation films 16 formed by the above methods.

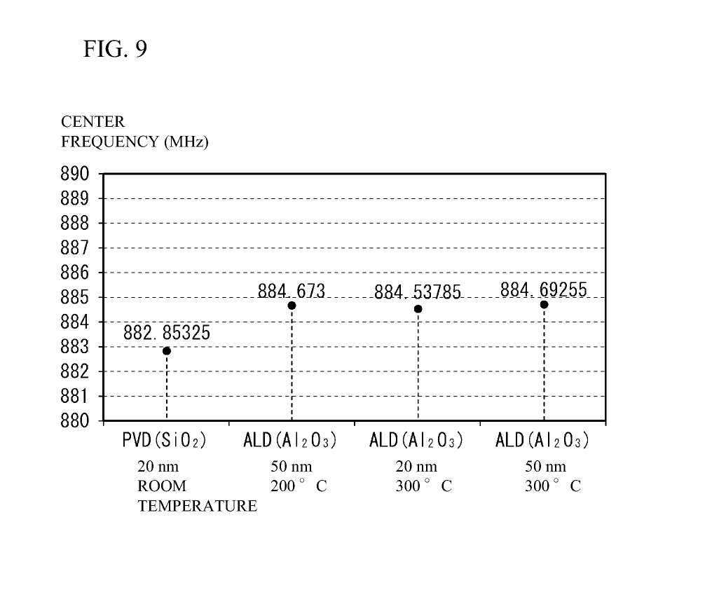

FIG. 9 is a graph of experimental results in which four pieces of data are illustrated. The leftmost piece of data illustrated in FIG. 9 is the experimental result of the PVD method, and the remaining three pieces of data are the experimental results of the ALD method. As illustrated in FIG. 9, the center frequencies of the samples with the insulation film 16 formed by the ALD method hardly change even when the film thickness or the growth temperature is changed, as in the case of FIG. 4C.

FIG. 10 is a schematic plan view of a variation of DMS filters connected in series. In addition to the structure illustrated in FIG. 8, a resonator 54 is provided between the first filter 50 and the input terminal In. The present variation with the insulation film 16 formed by the ALD method has stabilized filter characteristics as in the case of the structure illustrated in FIG. 8.

As described above, the filter characteristics of the acoustic wave device using the DMS filters connected in series can be stabilized by forming the insulation film 16 by the ALD method, as in the case of the acoustic wave device using the DMS filters connected in parallel. According to an aspect of the present invention, the acoustic wave device is not limited to the embodiments and variations described above, but includes various types of filters (for example, ladder type filers).

A description is given of a relationship between the methods of forming the insulation film 16 and the reliabilities.

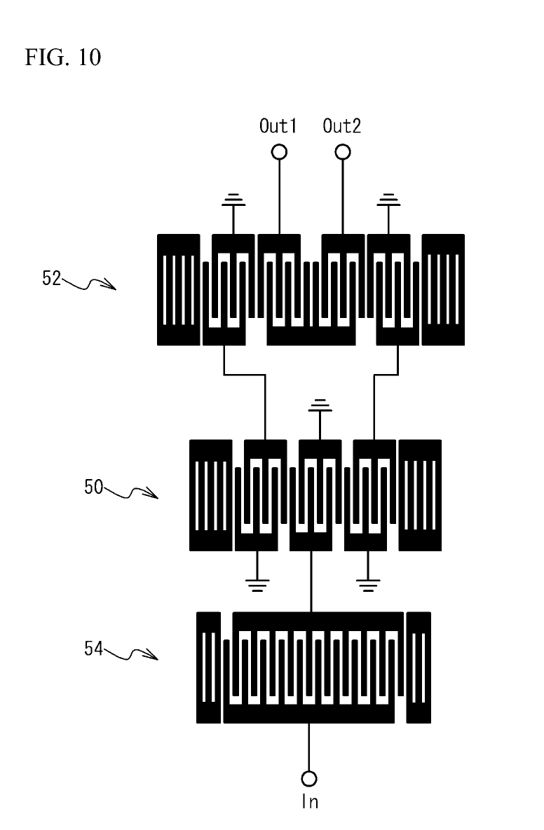

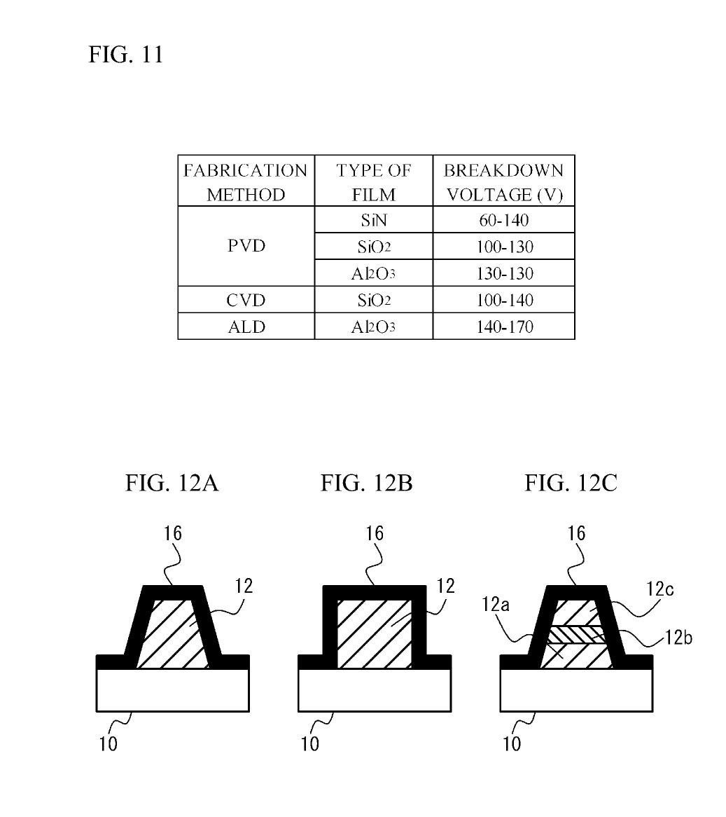

FIG. 11 illustrates a relationship between the method of forming the insulation film and the breakdown voltage of the interdigitated electrodes 12. The left column in FIG. 11 indicates the method of forming the insulation film 16, the center column indicates the type (material) of the insulation film 16, and the right column indicates the breakdown voltage. The breakdown voltage was measured by applying a voltage between the two solder balls 28 of the acoustic wave device illustrated in FIG. 2C. The minimum value of the breakdown voltage is the voltage observed when electrostatic breakdown begins, and the maximum value thereof is the voltage observed when electrostatic breakdown occurs completely.

As illustrated in FIG. 11, for the PVD or CVD method, the maximum value of the breakdown voltage was 130 V˜140 V irrespective of the type of the insulation film 16. In contrast, for the ALD method, the minimum value of the breakdown voltage was 140 V, and the maximum value thereof was 170 V. This means that the ALD method realizes an improved resistance to electrostatic breakdown, as compared with the other methods. The insulation film 16 formed by the ALD method suppresses electrostatic breakdown of the interdigitated electrodes 12 and improves the reliability of the acoustic wave device.

The insulation film 16 formed by the ALD method exhibits a good coverage, as compared with the other methods. This is now described in more detail below.

FIGS. 12A through 12C are enlarged cross-sectional views of one finger of the interdigitated electrodes 12. FIG. 12A illustrates the structure of the first embodiment, and FIGS. 12B and 12C illustrate variations thereof. As illustrated in FIG. 12A, the side surface of the electrode finger used in the first embodiment has a tapered shape that gradually becomes wider towards the piezoelectric substrate 10. The insulation film 16 has a shape that corresponds to the tapered side surface of the electrode finger. In FIG. 12B, the side surfaces of the electrode finger are vertical to the piezoelectric substrate 10. In the PVD and CVD methods, it is difficult to form an insulation film having a good coverage on vertical planes. In contrast, the ADL method is capable of forming an insulation film having a good coverage on the vertical planes, as illustrated in FIG. 12B. The use of the ALD method for forming the insulation film 16 is particularly effective to a case where the side surfaces of the fingers of the interdigitated electrodes 12 have a large angle of inclination (for example, 90° as in the case of FIG. 12B).

FIG. 12C illustrates an exemplary multilayer structure of the interdigitated electrodes 12. For example, the interdigitated electrodes 12 include a cupper layer and an aluminum layer. In FIG. 12C, the interdigitated electrodes 12 include a first aluminum layer 12a, a copper layer 12b and a second aluminum layer 12c, which layers are serially stacked in this order from the piezoelectric substrate 10. The side surfaces of the electrode finger are tapered like those illustrated in FIG. 12A.

When aluminum oxide is used to form the insulation film 16, a defect tends to occur in a copper portion of the interdigitated electrodes 12 covered with the insulation film 16 formed by the PVD or CVD method, because aluminum oxide does not adhere to copper well. On the contrary, the insulation film 16 formed by the ALD method has a good coverage. Thus, the use of the ALD method for forming the insulation film 16 is particularly advantageous to a case where the interdigitated electrodes 12 include copper (for example, in a case where the interdigitated electrodes 12 are made of an alloy of copper and aluminum).

### Second Embodiment

A second embodiment has an exemplary structure in which a barrier film is formed on the insulation film that covers the interdigitated electrodes.

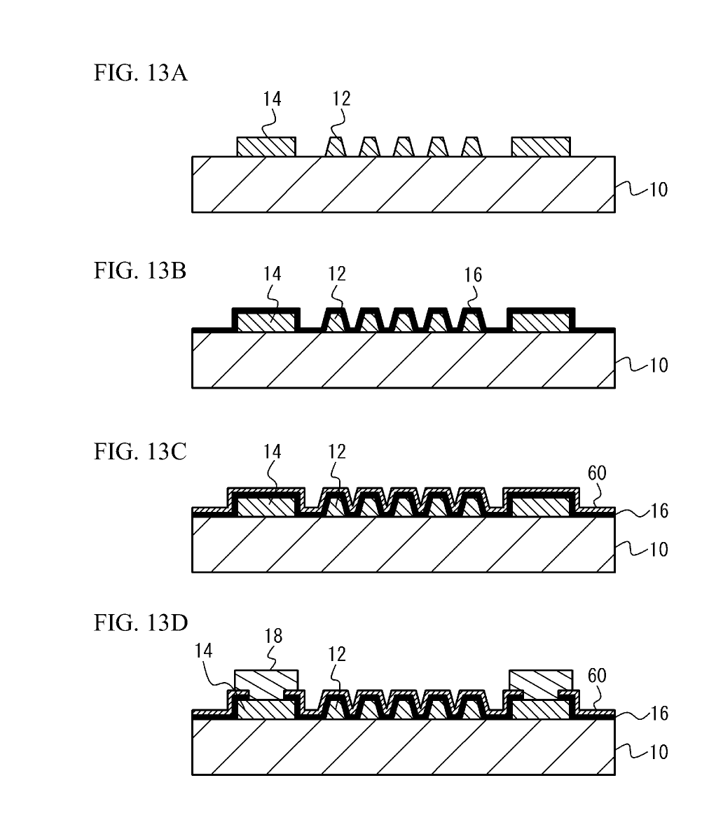

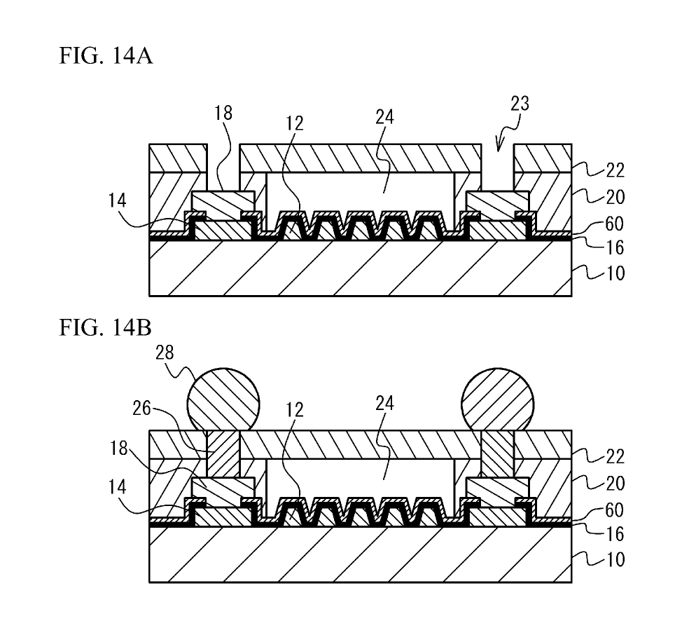

FIGS. 13A through 13D and FIGS. 14A and 14B illustrate a method for fabricating an acoustic wave device according to the second embodiment. As illustrated in FIGS. 13A and 13B, the interdigitated electrodes 12 and the electrode pads 14 are formed on the piezoelectric substrate 10, and the insulation film 16 are formed so as to cover the interdigitated electrodes 12 and the electrode pads 14. These steps are the same as those that have been described with reference to FIGS. 1A and 1B, a repetitive description thereof is omitted here.

In the second embodiment, the piezoelectric substrate 10 may be made of a piezoelectric crystal such as LiTaO₃. The interdigitated electrodes 12 and the electrode pads 14 may be made of an Al—Cu alloy (a few % Al is added to Cu) and may be 350 nm thick, for example. The insulation film 16 may be made of, for example, aluminum oxide (Al₂O₃) and may be 50 nm thick, for example. Like the first embodiment, the insulation film 16 is formed by the ALD method (which includes the thermal ALD method and the plasma ALD method).

Next, as illustrated in FIG. 13C, a barrier film 60 is formed on the insulation film 16. The barrier film 60 is a thin film formed on the surface of the insulation film 16, and may be 10 nm thick, for example. The barrier film 60 may be a film including silicon oxide (SiO₂ thermally oxidized film) formed by the CVD method.

As illustrated in FIG. 13D, part of the insulation film 16 and the barrier film 60 are removed to expose the electrode pads 14. Then, the metal layer 18 is formed on the exposed upper surfaces of the electrode pads 14 and the barrier film 60 above the electrode pads 14. The metal layer 18 may be formed by stacking Ti and Au in this order from the exposed surfaces of the electrode pads 14, and may be 650 nm thick, for example.

Then, as illustrated in FIG. 14A, the seal layers 20 and 22 are formed. The thickness from the piezoelectric substrate 10 to the upper surface from the seal layer 22 may be 75 μm, for example. Subsequently, as illustrated in FIG. 14B, the electrode posts 26 and the solder balls 28 are formed. The steps of FIGS. 14A and 14B are the same as those that have been described with reference to FIGS. 1D and 1E, and a repetitive description thereof is omitted here.

The acoustic wave device of the second embodiment is configured to have the barrier film 60 on the insulation film 16. In the package having a hollow structure by resin molding, a problem may arise from the insulation film 16 made of aluminum oxide on the interdigitated electrodes 12. More particularly, aluminum oxide change to boehmite aluminum oxide in high-temperature water vapor in a pressure cooker test, which is a kind of reliability test. Thus, the insulation film 16 has an increasing weight, which causes a deterioration of the filter characteristics. The barrier film 60 (thermally oxidized SiO₂ by the CVD method) on the surface of the insulation film 16 employed in the second embodiment suppress the change of aluminum oxide to boehmite alumina. Thus, it is possible to suppress the deterioration of the filter characteristics and improve the reliability.

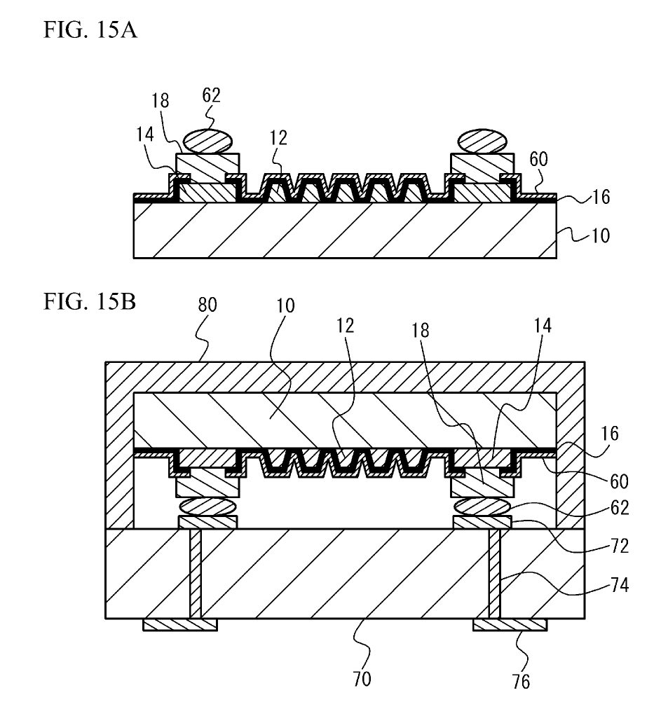

In the second embodiment, as illustrated in FIGS. 14A and 14B, the seal layers 20 and 22 and the electrode posts 26 are formed on the metal layer 18. However, electrical connections may be made by a method other than the above. FIGS. 15A and 15B illustrate a method for fabricating an acoustic wave device in accordance with a variation of the second embodiment. The steps of the method up to the formation of the metal layer 18 is the same as those illustrated FIGS. 13A through 13C, and a repetitive description thereof is omitted here.

As illustrated in FIG. 15A, metal bumps 62 are formed on the metal layer 18. The metal bumps 62 may be gold bumps, for example. The acoustic wave device with the metal bumps 62 are facedown mounted on a mount substrate 70. Electrode pads 72 are formed on the mount substrate 70 in positions corresponding to the metal bumps 62. The metal bumps 62 are in contact with the electrode pads 72 and are electrically connected thereto. The electrode pads 72 are connected to electrode patterns 76 via through electrodes 74 provided in the mount substrate 70.

The acoustic wave device is mounted on the mount substrate 70, and the upper surfaces of the mount substrate 70 and the piezoelectric substrate 10 are sealed with seal resin 80. Thus, the acoustic wave device in accordance with the variation of the second embodiment is packaged. The barrier film 60 formed on the insulation film 16 prevents the filter characteristics from deteriorating and improves the reliability.

The present invention is not limited to the SAW filters used in the first and second embodiments but may include any acoustic wave devices capable of transmitting signals using acoustic waves. For example, the present invention includes a boundary acoustic wave filter and a Love-type filter.

The present invention is not limited to the specifically described embodiments and variations but includes other embodiments and variations within the scope of the claimed invention.

What is claimed is:

1. An acoustic wave device comprising:
a piezoelectric substrate;
interdigitated electrodes formed on the piezoelectric substrate; and
an insulation film that is formed on a surface of the interdigitated electrodes by atomic layer deposition and includes aluminum oxide.

2. The acoustic wave device according to claim 1, wherein the interdigitated electrodes includes one of aluminum and aluminum alloy.

3. The acoustic wave device according to claim 2, wherein the aluminum alloy includes copper.

4. The acoustic wave device according to claim 1, comprising a seal layer provided so as to cover the interdigitated electrodes, wherein a cavity located above the interdigitated electrodes is defined by the seal layer.

5. The acoustic wave device according to claim 1, wherein the interdigitated electrodes have side surfaces that are vertical to a surface of the piezoelectric substrate.

6. The acoustic wave device according to claim 1, wherein the interdigitated electrodes have a multilayer structure composed of multiple metal layers.

7. The acoustic wave device according to claim 1, further comprising a barrier layer that is formed on a surface of the insulation film by chemical vapor deposition and includes silicon oxide.

8. A method for fabricating an acoustic wave device comprising:
forming interdigitated electrodes on a piezoelectric substrate; and
forming an insulation film including aluminum oxide on a surface of the interdigitated electrodes by atomic layer deposition.

9. The method according to claim 1, further comprising forming a barrier layer including silicon oxide on a surface of the insulation film by chemical vapor deposition.
